(19) United States
(12) Patent Application Publication
(10) Pub. No.: US 2022/0170993 A1
(43) Pub. Date: Jun. 2, 2022

(54) METHOD FOR DETERMINING THE STATE OF HEALTH OF AN ELECTRICAL ENERGY STORE, COMPUTER PROGRAM PRODUCT, AND MACHINE-READABLE MEMORY MEDIUM

(71) Applicant: Robert Bosch Gmbh, Stuttgart (DE)

(72) Inventor: Christoph Woll, Gerlingen (DE)

(21) Appl. No.: 17/456,441

(22) Filed: Nov. 24, 2021

(30) Foreign Application Priority Data
Nov. 27, 2020 (DE) 10 2020 214 917.8

(51) Int. Cl. G01R 31/392; G01R 31/367

(52) U.S. Cl. CPC G01R 31/392; G01R 31/367

(57) ABSTRACT

A method for determining a state of health of an electrical energy store. An operating state of the electrical energy store being detected. At least two models and/or measuring methods for determining the state of health of the electrical energy store are selected as a function of the operating state. The state of health of the electrical energy store is determined using the first measuring method or model. The state of health of the electrical energy store is determined using the further measuring method or model. The values for the state of health of the electrical energy store, determined with the aid of the various measuring methods and/or models, are evaluated, taking into account the operating state, and the value of the state of health having the greatest accuracy being output.

### FIELD

The present invention relates to a method for determining the state of health of an electrical energy store, a computer program product, and a machine-readable memory medium.

### BACKGROUND INFORMATION

PCT Patent Application No. WO 2017/182497 A1 describes a method and a system for assessing an electrochemical memory unit.

PCT Patent Application No. WO 2019/199219 A1 describes methods and control units for determining an extended state of health of a component and for controlling the component.

### SUMMARY

In accordance with an example embodiment of the present invention, a method is provided for determining the state of health of an electrical energy store which includes the following method steps: an operating state of the electrical energy store is detected in a first method step, at least two models and/or measuring methods for determining the state of health of the electrical energy store are selected in a second method step as a function of the operating state, data for determining the state of health of the electrical energy store are detected in a third method step with the aid of a first measuring method or model, the state of health of the electrical energy store is determined in a fourth method step with the aid of the first measuring method or model, data for determining the state of health of the electrical energy store are detected in a further method step with the aid of a further measuring method or model, the state of health of the electrical energy store is determined in a further method step with the aid of the further measuring method or model, the values for the state of health of the electrical energy store, determined with the aid of the various measuring methods and/or models, are evaluated in a further method step, taking into account the operating state, and the value of the state of health having the greatest accuracy is output.

The present invention provides an improved accuracy of the values of the state of health. As the result of always outputting the value for the state of health that was determined using the model or measuring method and that delivers the most accurate value for the state of health as a function of the operating state, the scattering of the values of the state of health may be reduced.

It is advantageous that multiple models or measuring methods are always simultaneously used, or data for determining the state of health for multiple models or measuring methods are always simultaneously detected, so that in the event of short-term changes in the operating state it is always possible to output the most accurate value for the state of health.

In addition, the accuracy in determining the state of charge of the electrical energy store may also be improved.

Further advantageous specific embodiments of the present invention are disclosed herein.

According to one advantageous embodiment of the present invention, those models and/or measuring methods that deliver the most accurate value for the state of health for the present operating state are selected in the second method step. In this way, the value to be output for the state of health may be selected from multiple values with great accuracy. The scattering of the determined values is reducible. If one of the determined values deviates from the other values by an unexpectedly high extent, an error in the data may be recognized.

It is advantageous when, in selecting the models and/or measuring methods, a method is used that applies machine learning, in particular the operating state, measuring methods and/or models, and states of health of a plurality of electrical energy stores being evaluated in order to associate the particular measuring method and/or model having the greatest accuracy with a particular operating state. The accuracy and robustness of the method may be further improved in this way.

Furthermore, it is advantageous when, in determining the value for the state of health having the greatest accuracy, a method is used that applies machine learning, in particular the operating state, measuring methods and/or models, and states of health of a plurality of electrical energy stores being evaluated in order to associate the particular measuring method and/or model having the greatest accuracy with a particular operating state. The accuracy and robustness of the method may be even further improved in this way.

According to a further advantageous embodiment of the present invention, the state of health determined in the fourth method step is used to correct a parameter of the further model or measuring method, in particular the corrected parameters being used to determine the state of health of the electrical energy store with the aid of the further measuring method or model. In this way, the various measuring methods and models may be mutually optimized and the accuracy of the method may be further improved.

For this purpose, the data for determining the state of health of the electrical energy store with the aid of the various measuring methods or models are advantageously detected simultaneously.

In addition, it is advantageous when a future course of the state of health is predicted, in particular a model being used whose parameters have been corrected with the aid of the determined values for the state of health. A vehicle-individual optimization of the service life of the individual electrical energy store may be achieved in this way.

An operating state is advantageously a dynamic operation or a stationary operation of the electrical energy store, in particular the charging or discharging of the electrical energy store at an associated charge rate or discharge rate, and/or a balancing state of the electrical energy store, and/or a maintenance state in a repair shop.

Moreover, it is advantageous when the models for determining the state of health of the electrical energy store include at least one physical model, in particular the physical model using an electrical equivalent circuit diagram for the electrical energy store with current integration for determining the charge quantity, and/or an electrochemical model. The state of health of the electrical energy store is determinable with differing accuracy for each operating state with the aid of the models. The models have a high level of data availability.

In addition, it is advantageous when the measuring methods for determining the state of health of the electrical energy store include at least measuring methods with charge quantity determination at defined voltage levels, in particular after a balancing operation, and/or measuring methods with determination of the open circuit voltage upon calling up of the balancing function after a defined switch-off time of the electrical energy store, and/or repair shop measurements. The state of health of the electrical energy store for a certain operating state may be determined extremely accurately with the aid of the measuring methods, and these values may be used to correct parameters of the models.

The above embodiments and refinements may be arbitrarily combined with one another if this is meaningful. Further possible embodiments, refinements, and implementations of the present invention also include combinations, even if not explicitly stated, of features of the present invention which are described above or below with regard to the exemplary embodiments. In particular, those skilled in the art will also add individual aspects as enhancements or supplements to the particular basic form of the present invention, in view of the disclosure herein.

### BRIEF DESCRIPTION OF THE DRAWINGS

The present invention is explained in the following section, based on exemplary embodiments from which further inventive features may arise, but to which the scope of the present invention is not limited. The exemplary embodiments are illustrated in the figures.

FIG. 1 shows a schematic flowchart of method 100 according to an example embodiment of the present invention for determining the state of health of an electrical energy store.

FIG. 2 shows a graphical illustration of state of health SOH of an electrical energy store as a function of time t.

### DETAILED DESCRIPTION OF EXAMPLE EMBODIMENTS

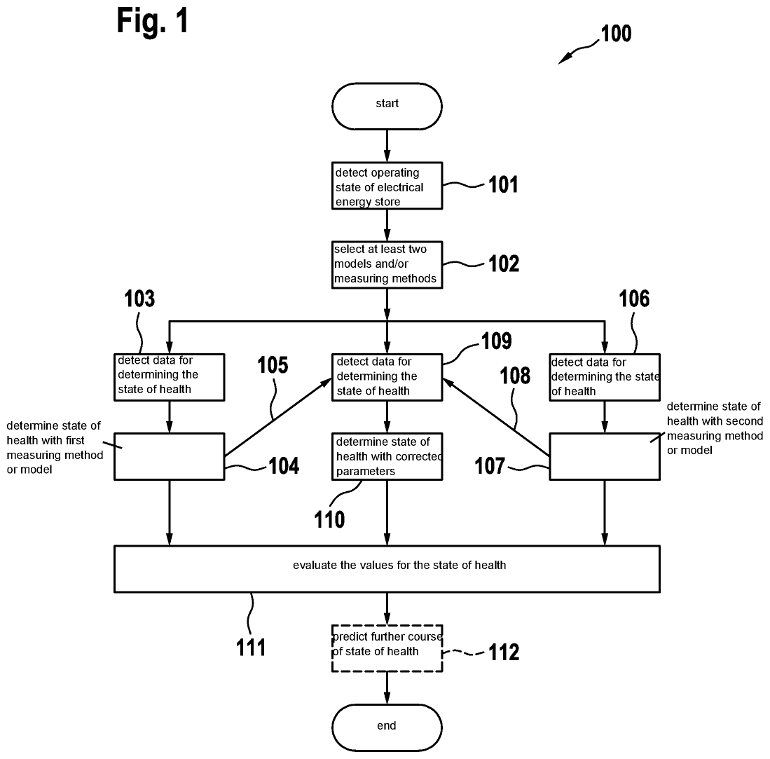

FIG. 1 illustrates a flowchart of method 100 according to an example embodiment of the present invention for determining the state of health of an electrical energy store.

After the method is started, an operating state of the electrical energy store is detected in a first method step 101.

An operating state is, for example, a dynamic operation or a stationary operation or the charging or discharging of the electrical energy store at an associated charge rate or discharge rate, or a balancing state of the electrical energy store, in which the charge quantities of electrical energy store cells of the electrical energy store are equalized, or a maintenance state in a repair shop.

At least two models and/or measuring methods for determining the state of health of the electrical energy store are selected in a second method step 102 as a function of the operating state. Those models and/or measuring methods that deliver the most accurate value for the state of health for the present operating state are selected.

A method that applies machine learning is preferably used in selecting the models and/or measuring methods. The operating state, measuring methods and/or models, and states of health of a plurality of electrical energy stores are evaluated in order to associate the particular measuring method and/or model having the greatest accuracy with a particular operating state.

The models for determining the state of health of the electrical energy store include at least one physical model, which for example uses an electrical equivalent circuit diagram for the electrical energy store with current integration for determining the charge quantity, and/or an electrochemical model.

The measuring methods for determining the state of health of the electrical energy store include at least measuring methods with charge quantity determination at defined voltage levels, in particular after a balancing operation, and/or measuring methods with determination of the open circuit voltage upon calling up of the balancing function after a defined switch-off time of the electrical energy store, and/or repair shop measurements.

Data for determining the state of health of the electrical energy store are detected in a third method step 103 with the aid of a first measuring method or model.

The state of health of the electrical energy store is determined in a fourth method step 104 with the aid of the first measuring method or model.

The state of health determined in fourth method step 104 is used to correct a parameter of at least one further model or measuring method in a fifth method step 105.

Data for determining the state of health of the electrical energy store are detected in a sixth method step 106, which in particular runs simultaneously with third method step 103, with the aid of a second measuring method or model.

The state of health of the electrical energy store is determined in a seventh method step 107, which in particular runs simultaneously with fourth method step 104, with the aid of the second measuring method or model.

The state of health determined in seventh method step 107 is used in an eighth method step 108, which in particular runs simultaneously with fifth method step 105, in order to correct a parameter of at least one further model or measuring method.

Data for determining the state of health of the electrical energy store are detected in a ninth method step 109, which in particular runs simultaneously with third method step 103 and/or sixth method step 106, with the aid of a third measuring method or model.

The state of health of the electrical energy store is determined in a tenth method step 110 with the aid of the third measuring method or model, using the corrected parameters of the first measuring method or model and/or of the second measuring method or model.

The values for the state of health of the electrical energy store, determined with the aid of the various measuring methods and/or models, are evaluated in an eleventh method step 111, taking into account the operating state, and the value of the state of health having the greatest accuracy is output.

A method that applies machine learning is preferably used in determining the value for the state of health having the greatest accuracy. The operating state, measuring methods and/or models, and states of health of a plurality of electrical energy stores are evaluated in order to associate the particular measuring method and/or model having the greatest accuracy with a particular operating state.

The accuracy is a criterion for the quality of a measuring method or a model when it is applied for the present operating state. For example, physical models determine the state of health in stationary operation more precisely than in dynamic operation. In contrast, electrochemical models are more accurate in dynamic operation. The various measuring methods are suitable in each case for certain operating states, and for these operating states determine the state of health very precisely, so that these values are very well suited for correcting the parameters of the models.

A future course of the state of health is predicted in a twelfth method step 112. For this purpose, a model is used whose parameters have been corrected with the aid of the determined values for the state of health.

The method is ended after twelfth method step 112.

The individual method steps may be carried out completely or partially by a controller of the electrical energy store and/or an external control unit that is connected to the electrical energy store in a data-conducting manner.

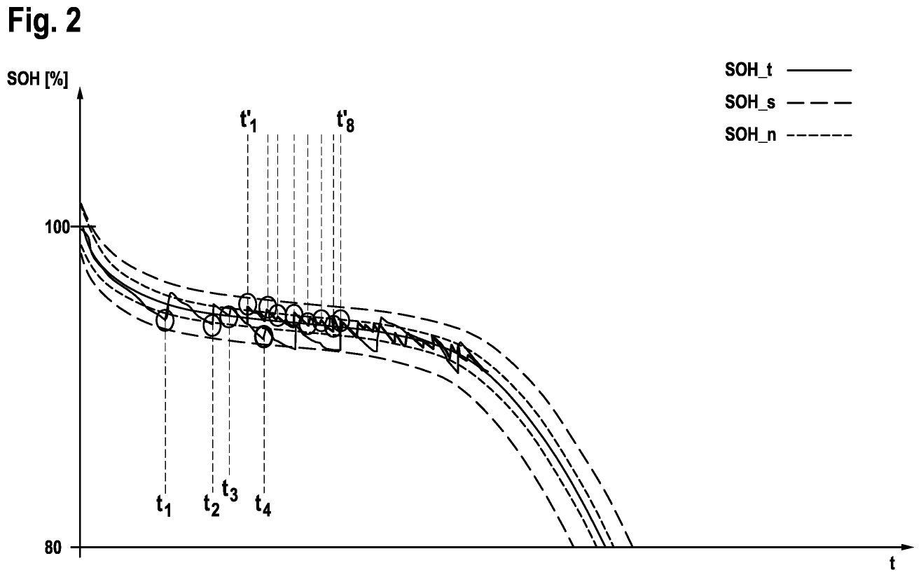

FIG. 2 illustrates the time curve of actual state of health SOH_t, an estimate of the time curve of state of health SOH_s as determined in the related art, and an estimate according to the present invention of the time curve of state of health SOH_n.

According to the related art, state of health SOH_s is estimated at various points in time (t1, t2, t3, t4). The values of state of health SOH_s fluctuate about the actual curve of state of health SOH_t and have a certain scattering.

In method 100 according to the present invention, state of health SOH_n of the electrical energy store is determined using various measuring methods or models, and thus more frequently, in particular approximately with twice the frequency as in the related art, for various operating states. According to the present invention, state of health SOH_n is determined at points in time t′1, t′2, t′3, t′4, t′5, t′6, t′7, and t′8. The deviation of the values of state of health SOH_n, determined according to the present invention, from the actual curve of state of health SOH_t is less than in the related art. The values of state of health SOH_n determined according to the present invention have a lesser scattering.

An electrical energy store is understood to mean a rechargeable energy store, in particular including an electrochemical energy store cell, and/or an energy store module including at least one electrochemical energy store cell, and/or an energy store pack including at least one energy store module. The energy store cell may be designed as a lithium-based battery cell, in particular a lithium-ion battery cell. Alternatively, the energy store cell is designed as a lithium-polymer battery cell or nickel-metal hydride battery cell or lead-acid battery cell or lithium-air battery cell or lithium-sulfur battery cell.

The electrical energy store is preferably used in a vehicle. A vehicle is understood to mean a land vehicle, for example a passenger automobile or a truck, or an aircraft or a watercraft, in particular an at least partially electrically driven vehicle. The vehicle is, for example, a battery-powered electric vehicle including a purely electric drive, or a hybrid vehicle including an electric drive and an internal combustion engine. Alternatively, the electrical energy store may also be used to operate an electrically driven work machine.

1-11. (canceled)

12. A method for determining a state of health of an electrical energy store, comprising the following steps:
detecting an operating state of the electrical energy store in a first method step;
selecting as a function of the detected operating state, at least two models and/or measuring methods for determining the state of health of the electrical energy store;
detecting data for determining the state of health of the electrical energy store using a first model and/or measuring method of the at least two models and/or measuring methods;
determining the state of health of the electrical energy store using the first model and/or measuring method;
detecting data for determining the state of health of the electrical energy store using a further model and/or measuring method of the at least two models and/or measuring methods;
determining the state of health of the electrical energy store using the further model and/or measuring method;
evaluating values for the state of health of the electrical energy store, determined using the first model and/or measuring method and the further model and/or measuring method, taking into account the detected operating state; and
outputting a value of the values of the state of health having a greatest accuracy.

13. The method as recited in claim 12, wherein those models and/or measuring methods that deliver the most accurate value for the state of health for the present operating state are selected in the selecting step.

14. The method as recited in claim 13, wherein in the selecting of the at least two models and/or measuring methods, a method is used that applies machine learning, in which the detected operating state, measuring methods and/or models, and states of health of a plurality of electrical energy stores are evaluated in order to associate a particular model and/or measuring having a greatest accuracy with a particular operating state.

15. The method as recited in claim 12, wherein in determining the value for the state of health having the greatest accuracy, a method is used that applies machine learning, in which particular the operating state, measuring methods and/or models, and states of health of a plurality of electrical energy stores being evaluated in order to associate the particular measuring method and/or model having the greatest accuracy with a particular operating state.

16. The method as recited in claim 12, wherein the state of health determined using the first model and/or measuring method is used to correct at least one parameter of the further model and/or measuring method, the at least one corrected parameter being used to determine the state of health of the electrical energy store using the further model and/or measuring method.

17. The method as recited in claim 12, further comprising:
predicting a future course of the state of health, a model being used whose parameters have been corrected using the determined values for the state of health.

18. The method as recited in claim 12, wherein the operating state is: (i) a dynamic operation or a stationary operation of the electrical energy store, and/or (ii) a charging or discharging of the electrical energy store at an associated charge rate or discharge rate, and/or (iii) a balancing state of the electrical energy store, and/or (iv) a maintenance state in a repair shop.

19. The method as recited in claim 12, wherein the at least two models and/or measuring methods for determining the state of health of the electrical energy store include at least one physical model using an electrical equivalent circuit diagram for the electrical energy store with current integration for determining charge quantity and/or an electrochemical model.

20. The method as recited in claim 12, wherein the at least two models and/or measuring methods for determining the state of health of the electrical energy store include a measuring method with charge quantity determination at defined voltage levels after a balancing operation, and/or a measuring method with determination of an open circuit voltage upon calling up of the balancing function after a defined switch-off time of the electrical energy store, and/or repair shop measurements.

21. A non-transitory machine-readable memory medium on which is stored a computer program that includes commands for determining a state of health of an electrical energy store, commands, when executed by a least one data processing device, causing the at least one data processing device to perform the following steps:
detecting an operating state of the electrical energy store in a first method step;
selecting as a function of the detected operating state, at least two models and/or measuring methods for determining the state of health of the electrical energy store;
detecting data for determining the state of health of the electrical energy store using a first model and/or measuring method of the at least two models and/or measuring methods;
determining the state of health of the electrical energy store using the first model and/or measuring method;
detecting data for determining the state of health of the electrical energy store using a further model and/or measuring method of the at least two models and/or measuring methods;
determining the state of health of the electrical energy store using the further model and/or measuring method;
evaluating values for the state of health of the electrical energy store, determined using the first model and/or measuring method and the further model and/or measuring method, taking into account the detected operating state; and
outputting a value of the values of the state of health having a greatest accuracy.
